(19) United States
(12) Patent Application Publication
(10) Pub. No.: US 2026/0045440 A1
(43) Pub. Date: Feb. 12, 2026

(54) CREATION OF ELECTRON BEAMS USING A MICRO-DEFLECTOR ARRAY

(71) Applicant: KLA Corporation, Milpitas, CA (US)

(72) Inventors: Xinrong Jiang, Palo Alto, CA (US); Alan D. Brodie, Palo Alto, CA (US)

(21) Appl. No.: 18/901,626

(22) Filed: Sep. 30, 2024

Related U.S. Application Data
(60) Provisional application No. 63/682,169, filed on Aug. 12, 2024.

(51) Int. Cl. H01J 37/14; H01J 37/075; H01J 37/147; H01J 37/153

(52) U.S. Cl. CPC H01J 37/14; H01J 37/075; H01J 37/1472; H01J 37/153; H01J 2237/151; H01J 2237/1532

(57) ABSTRACT

A gun lens receives an electron beam or other particle beam, which is then divided into beamlets by an aperture array. Each of the beamlets is telecentric. A global imaging lens receives the beamlets from the aperture array. A micro deflector array on a plane of the global imaging lens includes deflectors configured to be individually controlled.

### CROSS-REFERENCE TO RELATED APPLICATIONS

This application claims priority to the provisional patent application filed Aug. 12, 2024 and assigned U.S. App. No. 63/682,169, the disclosure of which is hereby incorporated by reference.

### FIELD OF THE DISCLOSURE

This disclosure relates to electron beam systems.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

A scanning electron beam inspection tool can be used to inspect semiconductor devices, for instance, those fabricated on semiconductor wafers or other workpieces. Commercially-available electron beam-based inspection systems currently use a single electron beam column based on the principle of scanning electron microscopy. These systems have low throughput because the images are acquired pixel-by-pixel in a sequential manner. The scan field of view of a single electron beam can be limited in tens of microns due to optical blurs and distortion, and the motions of the stage holding the workpiece generally inspect an integrated circuit die in millimeters to tens of millimeters. Stage motions can lower the throughput severely. The low throughput with a single electron beam raises inspection costs, which can be undesirable for semiconductor manufacturers.

In other previous electron beam systems, electrons were focused by an electron gun lens (GL) into a telecentric electron beam with a relatively large diameter. The telecentric electron beam illuminated an aperture array (APA). After passing through the APA holes, the electrons could form hundreds of telecentric beamlets. Such a design had illumination optics between an electron beam source and the aperture array and projection optics between aperture array and the wafer. However, there were large field curvature (FC) blurs with the beamlets across the field of view (FOV) inside which all beams are deployed. The field curvature blur (drc) may be described as follows.

$${d}_{F C} = 2 * N A * Δ {z}_{prj}$$

Δ_{zprj} is the field curvature distance in the projection optics from any deflector to a wafer. NA is the numeric aperture of a beamlet. The field curvature blur is introduced due to the optical path difference between the center beam and off-axis beams in the projection optics. For instance, the field curvature blur may be d_{FC}=100 nm assuming NA-10 mrad and Δzₚᵣⱼ=5.0 micron. These field curvature blurs can be corrected with a field curvature corrector (FCC) array because it may not be possible to control the optics to remove them.

Improved systems and methods are needed.

### BRIEF SUMMARY OF THE DISCLOSURE

A system is disclosed in a first embodiment. The system includes an electron beam source configured to generate an electron beam, a gun lens disposed in a path of the electron beam, an aperture array that divides the electron beam into a plurality of beamlets, a global imaging lens that receives the beamlets from the aperture array, and a micro deflector array disposed on a plane of the global imaging lens. Each of the beamlets is telecentric. The micro deflector array includes a plurality of deflectors configured to be individually controlled.

The electron beam source may be a thermal field emission source.

The global imaging lens can focus the beamlets onto an intermediate image plane.

The system can include a global transfer lens and a global objective lens. The global transfer lens and the global objective lens may be in a path of the beamlets. The global transfer lens may be disposed in the path of the beamlets between the global objective lens and the global imaging lens. The path of the beamlets can form a crossover between the global transfer lens and the global objective lens.

The global imaging lens may be a magnetic lens. The micro deflector array may be disposed on a principal plane between pole pieces of the global imaging lens. In an instance, the system can include a micro stigmator array and a ground electrode plate disposed in the path of the beamlets. The ground electrode plate may be disposed along the path of the beamlets between the aperture array and the micro deflector array. The micro stigmator array may be disposed along the path of the beamlets between the aperture array and the ground electrode plate.

The deflectors may each be a hexapole, single polarity electrostatic deflector. The deflectors can be disposed on an insulation substrate. A diameter of an aperture of the deflectors may be at least two times larger than an aperture of the aperture array.

The beamlets may be configured in a hexagon array.

A method is provided in a second embodiment. The method includes generating a charged particle beam using a charged particle beam source. The changed particle beam is directed through a gun lens. The charged particle beam is directed through an aperture array thereby dividing the particle beam into a plurality of beamlets. Each of the beamlets is telecentric. The aperture array is downstream of the gun lens relative to a path of the particle beam. The beamlets are directed through a global imaging lens. The beamlets are deflected using a micro deflector array disposed on a plane of the global imaging lens. The micro deflector array includes a plurality of deflectors configured to be individually controlled. In an instance, the charged particle beam is an electron beam, and the charged particle beam source is a thermal field emission source.

The method can include focusing the beamlets onto an intermediate image plane using the global imaging lens.

The method can include directing the beamlets through a global transfer lens and a global objective lens. The global transfer lens may be disposed in a path of the beamlets between the global objective lens and the global imaging lens. The path of the beamlets can form a crossover between the global transfer lens and the global objective lens.

In an instance, the method can include directing the beamlets through a micro stigmator array and a ground electrode plate. The ground electrode plate may be disposed along the path of the beamlets between the aperture array and the micro deflector array. The micro stigmator array may be disposed along the path of the beamlets between the aperture array and the ground electrode plate.

The deflectors may each be a hexapole, single polarity electrostatic deflector. The deflectors may be disposed on an insulation substrate. A diameter of an aperture of the deflectors may be at least two times larger than an aperture of the aperture array.

The beamlets may be configured in a hexagon array.

Field curvature blurs from all the beamlets can be self-controllably corrected by adjusting image lens excitations of the global imaging lens.

### DESCRIPTION OF THE DRAWINGS

For a fuller understanding of the nature and objects of the disclosure, reference should be made to the following detailed description taken in conjunction with the accompanying drawings, in which:

FIG. 1 is a diagram of a system in accordance with the present disclosure;

FIG. 2 is a diagram of another system in accordance with the present disclosure;

FIG. 3 is a diagram of an electron projection optical column in accordance with the present disclosure;

FIG. 4 is an embodiment of an arrangement of electron beamlets;

FIG. 5 is an embodiment of beamlet creation;

FIG. 6 is an embodiment of a hexapole single-polarity electrostatic deflector;

FIG. 7 is an embodiment of deflection fields in a hexapole single-polarity electrostatic deflector;

FIG. 8 is a diagram of an embodiment of a micro deflector array on an insultation substrate;

FIG. 9 is a diagram of an embodiment of a dodecapole micro stigmator;

FIG. 10 is an embodiment of electrostatic fields in dodecapole micro stigmator with V=1.0 V;

FIG. 11 is an elevation view of a dodecapole micro stigmator on an insulation substrate; and

FIG. 12 is a diagram of an embodiment of a micro stigmator array on an insulation substrate.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein create multi electron beams (MEB), which can take the form of beamlets. Using a micro deflector array (MDA), the beamlets are created with a self-controllable adjustment of an image lens to automatically correct field curvature blurs without introducing additional deteriorations of optical performance. This can provide a geometry that is simpler that alternate designs. For example, six plates can be used in a single-polarity hexapole deflector. One power may be needed for the single-polarity hexapole deflector. Consequently, overall power usage may be reduced.

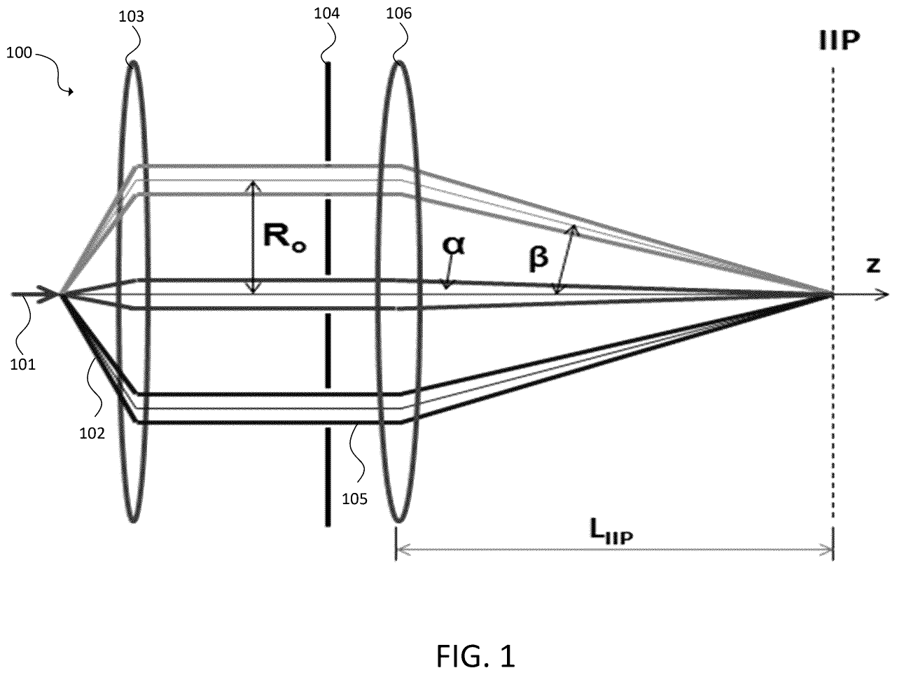

FIG. 1 shows how focused multi electron beams (e.g., beamlets) are created in a system 100 with an illumination beam and related optics. An electron beam source 101 (i.e., an emitter tip) is used to generate an electron beam 102. The electrons in the electron beam 102 from the electron beam source 101 (e.g., a thermal field emission source) are focused by a global gun lens (GL) 103 to form a large diameter (>>2R₀ in FIG. 1) electron beam 102. The global gun lens 103 is in the path of the electron beam 102. The large electron beam 102 may be collimated into a telecentric beam to illuminate an aperture array (APA) 104. Tens to hundreds of open holes may be arranged on plate of the aperture array 104. The hole size may be in tens of microns. After the aperture array 104, tens to hundreds of telecentric electron beamlets 105 may be formed. All these beamlets 105 may be simultaneously focused by a global imaging lens (IL) 106 onto an intermediate image plane (IIP). The global imaging lens 106, which can receive beamlets 105 from the aperture array 104, may be an electrostatic lens or a magnetic lens. For a better image-forming performance, a magnetic image lens (MIL) can be used, as shown in FIG. 1. However, an electrostatic lens also can be used. The global gun lens and magnetic image lens can be magnetic lenses for accepting larger illumination beam (or more beamlets) with smaller spherical aberration blurs.

The distance between the magnetic image lens and intermediate image plane, which is designated L_{IIP}, may affect performance. L_{IIP} is tunable with changing the magnetic excitation of the magnetic image lens. The half beamlet angle, α, can affect the final numeric aperture (NA) in the sample (e.g. wafer) side for balancing various image-forming aberrations. The general beam angle, β, may be defined by R₀ and L_{IIP} in FIG. 1.

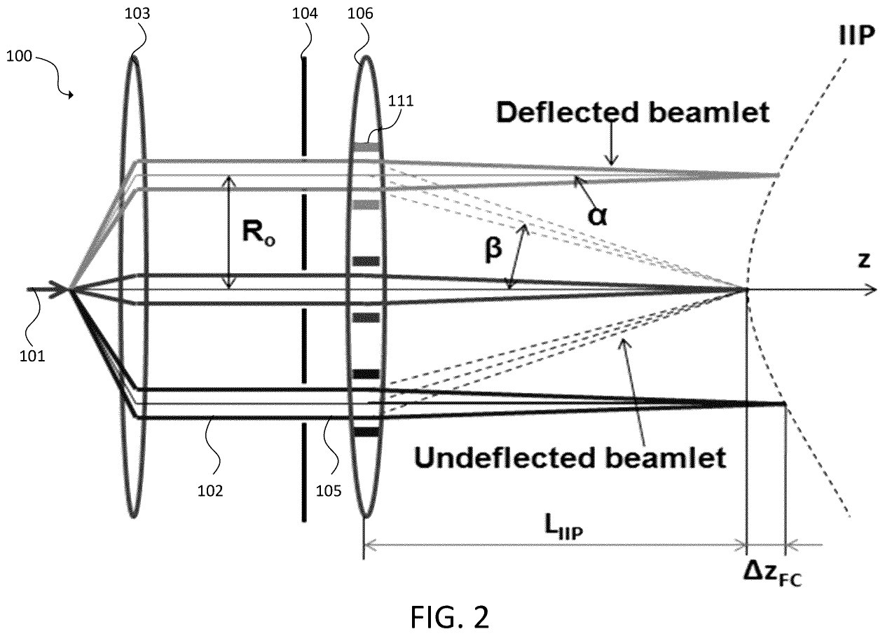

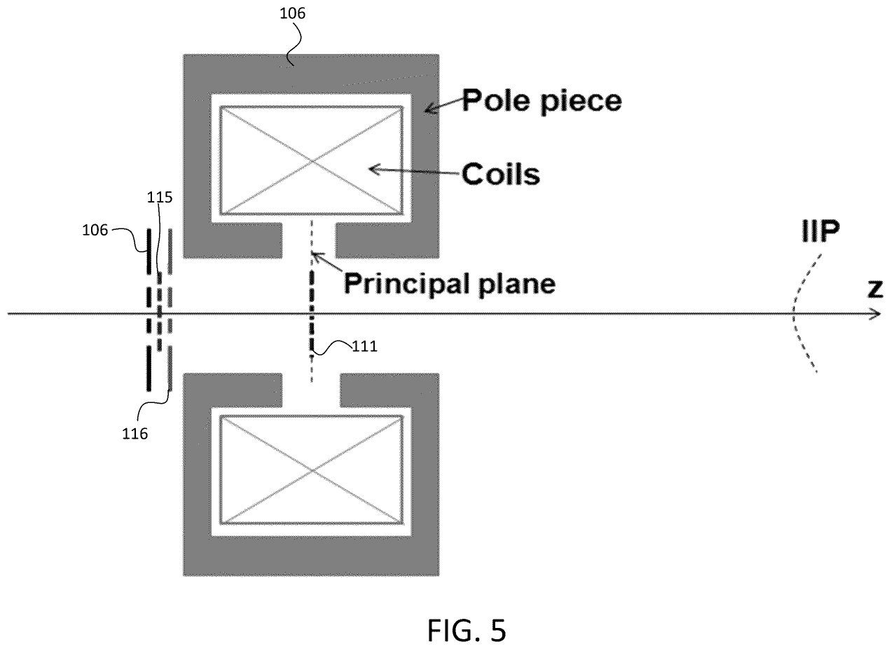

Besides affecting field curvature, L_{IIP} also can affect coma, astigmatism, and distortion. The coma is normally small and negligible because the angle α is small and the coma is proportional to α squared. The astigmatism can be corrected by the micro stigmator array (MSA) 115 in FIG. 5. The distortion can be corrected by the micro deflector array (MDA) 111 in FIG. 2 and FIG. 5.

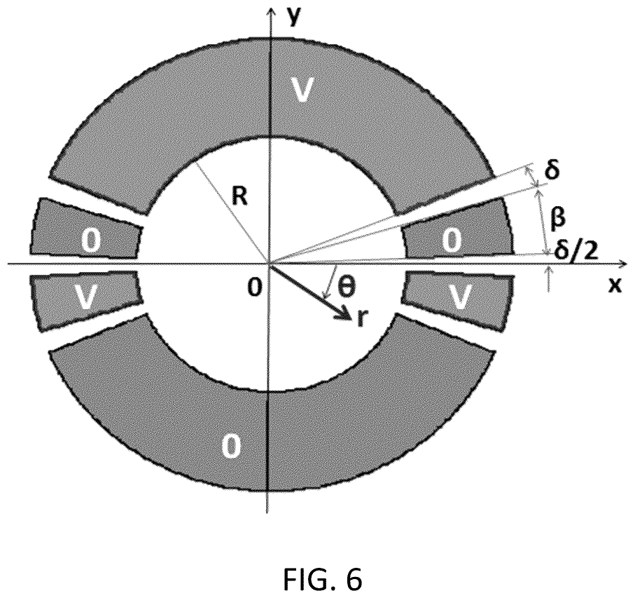

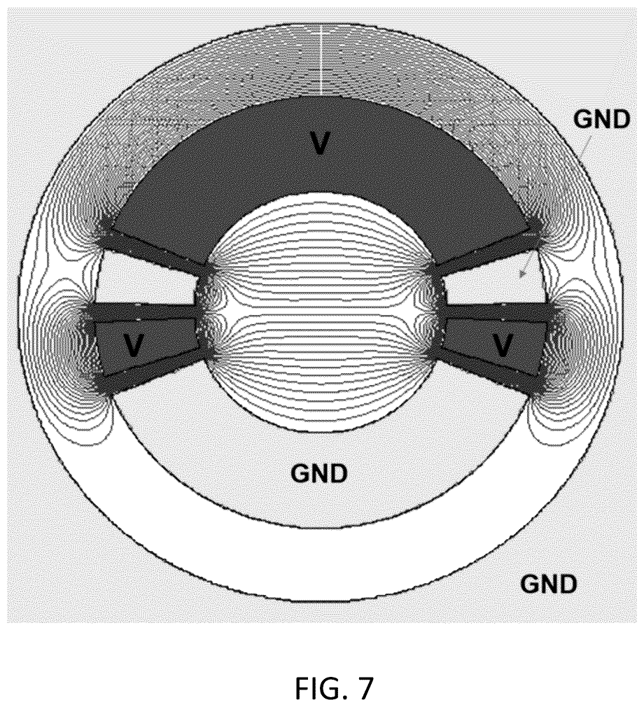

FIG. 2 shows the creation of separated beamlets in a system 110. A micro deflector array 111 may be used in the principal plane of the magnetic image lens (MIL) 106. In an instance, the micro deflector array 111 is positioned on the principal plane between the pole pieces. Each focused beamlet 105 may be independently deflected by an individual deflector in the micro deflector array 111. Thus, each micro deflector (e.g., around or in each of the apertures) in the micro deflector array 111 can be individually controlled. After deflection, these beamlets 105 may be formed a group of divergent, parallel (telecentric), or convergent beams, as shown in FIG. 2, in which a group of parallel beamlets 105 are imaged-formed in a quadratic-curved intermediate image plane. To individually monitor and adjust deflections for the beamlets 105, the hexapole single polarity deflector in FIG. 6 and FIG. 7 can deflect the beamlets 105. The beamlets 105 may be monitored on a YAG screen of a test stand when adjusting each beamlet 105 with each deflector.

As shown in FIG. 2, an off-axis deflected beamlet 105 has a longer image distance than a central beamlet 105. The difference of image distances may be referred to as field curvature distance, as described as Δz_{FC} in FIG. 2. The Δz_{FC} is a quadratic function of the off-axis distance r.

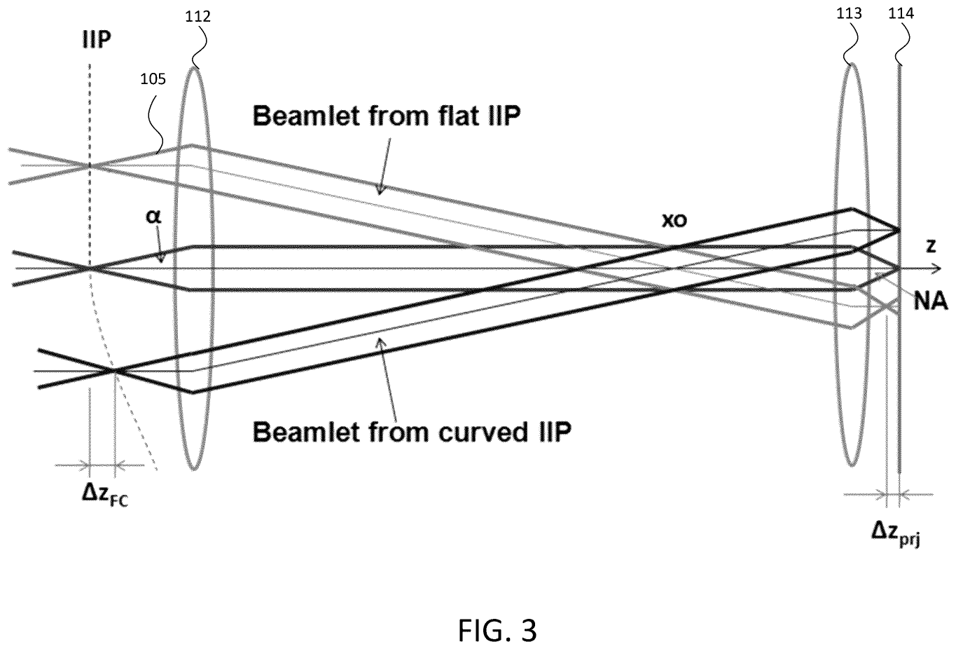

The beamlet field curvatures in FIG. 2 may be corrected with a lower electron optical column, such as the projection optical column from the intermediate image plane to wafer shown in FIG. 3. A projection optics includes a global transfer lens (TL) 112 and global objective lens (OL) 113. The object array on the intermediate image plane is image-formed on a workpiece 114 with an optical magnification from approximately 0.1× to 0.5×, which can meet throughput and secondary electron (SE) collection specifications. The global transfer lens 112 and the global objective lens 113 are in a path of the beamlets 105. The global transfer lens 112 is disposed in the path of the beamlets 105 between the global objective lens 113 and the global imaging lens 106. All beamlets 105 form a crossover (xo) around the back focal plane of the objective lens 113 for telecentric landing on the workpiece 114. The crossover can be between the global transfer lens 112 and the global objective lens 113.

Field curvatures exist in a projection optics, which can be seen in FIG. 3. In FIG. 3, if the beamlets 105 from a flat intermediate image plane are image-formed on the workpiece 114, there exists a field curvature distance Δzₚᵣⱼ in the wafer side because of optical path difference between the off-axis beam and central beam. If the beamlets 105 from a curved intermediate image plane and with a pre-set field curvature distance Δz_{FC} in the curved intermediate image plane side, the field curvature distance in the projection optics, Δzₚᵣⱼ, may be compensated if the Δz_{FC} is adjustable to meet certain conditions. These conditions may be described as follows.

The field curvature distance in FIG. 3, Δz_{FC}, may be determined using the following equation.

$$Δ {z}_{F C} \approx k \frac{{R}_{0}^{2}}{2 {L}_{IIP}}$$

R₀ and L_{IIP} are the illumination beam size and MIL image distance, respectively. k is a factor that depends on the image lens (IL) designs (i.e., is it a magnetic image lens or electrostatic image lens and what is the geometrical feature). The k may be determined with computer simulations or with calibrations after an optical column is constructed. The k may be much greater than 1.

If the magnetic image lens image distance in FIG. 2, LIP, is set to meet the following equation,

$${L}_{IIP} = {kM}^{2} \sqrt{\frac{L E}{B E}} \frac{{R}_{0}^{2}}{2 Δ {z}_{prj}}$$

then the field curvature of each beamlet at wafer in FIG. 3 is self-controllably corrected. M is the optical magnification from intermediate image plane to wafer, LE is the electron beam landing energy, and BE is the electron beam energy in the optical column.

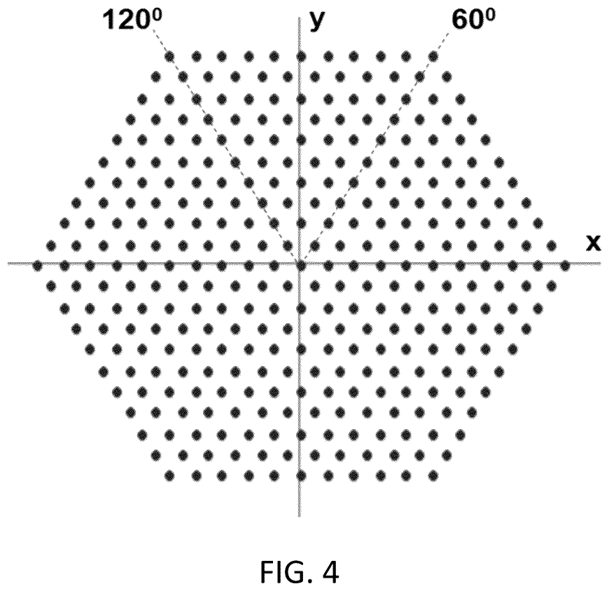

The beamlets may be arranged as a square array or a hexagon array. A hexagon array of 331 beams is shown in FIG. 4, meaning that the aperture array includes an array of 331 open holes and an array of 331 micro deflectors is used to separately deflect 331 beamlets with the micro deflector array. 331 electron beam spots are image-formed in the intermediate image plane. For a 331-beam optics with controllable projection optical performance, the pitch between the aperture holes may be around 100 μm, such the aperture hole size is around approximately 30 μm to 40 μm. While this example uses 331 beamlets, other numbers of beamlets are possible.

A hexagon beam arrangement may provide benefits compared to a square beam arrangement because a hexagon beam arrangement can have more electron beamlets for higher throughput assuming that their corner-to-corner distance is identical. Of course, other configurations are possible.

FIG. 5 shows an embodiment of a creation system of beamlets using a micro deflector array 111. The magnetic image lens (MIL) 105 includes magnetic pole pieces and excitation coils. The optical principal plane may be in the middle of the pole piece gap if the pole piece design is symmetrical in the optical axis z. The micro deflector array 111 may be deployed in the principal plane. In the front of magnetic image lens 105, the aperture array 104 (an example of which is shown in FIG. 4) is arranged. A micro stigmator array (MSA) 115 may be positioned between the aperture array 104 and ground electrode plate (GND) 116. The holes in the micro stigmator array 115, aperture array 106, and ground electrode plate 116 may be aligned in the same optical axis. The ground electrode plate 116 may be positioned along the path of the beamlets between the aperture array 104 and the micro deflector array 111. Following the magnetic image lens 106, a curved intermediate image plane is formed. The position of the curved intermediate image plane, Lu, may be adjustable by changing the excitation of the magnetic image lens coil current.

In an embodiment, the aperture array 104 hole size is smaller than the micro stigmator array 115 and ground electrode plate 116. The micro stigmator array 115 and ground electrode plate 116 hole sizes may be identical. For example, for a 331-beam optics with a 100 μm pitch, the aperture array 104 hole size may be 30 μm and the micro stigmator array 115 and ground electrode plate 116 hole sizes may be 50 μm.

The micro deflector array 111 in FIG. 5 may introduce negligible aberrations and distortion when deflecting an individual beamlet. A total number of signal lines for driving all the micro deflectors may be minimized because these lines are integrated in the micro deflector array chip. It can be difficult to integrate signal lines in the gaps between micro deflectors. Finally, deflection signal crosstalk between micro deflectors can be minimized or eliminated. A signal line number for the hexapole single polarity deflector can be at least 2× reduced compared to other deflectors (e.g., conventional octupole deflector). These signal lines can be integrated in the narrowed gaps between deflectors. With the reduced signal line number, the gap between the conductive signal lines is increased, such that crosstalk risks are reduced.

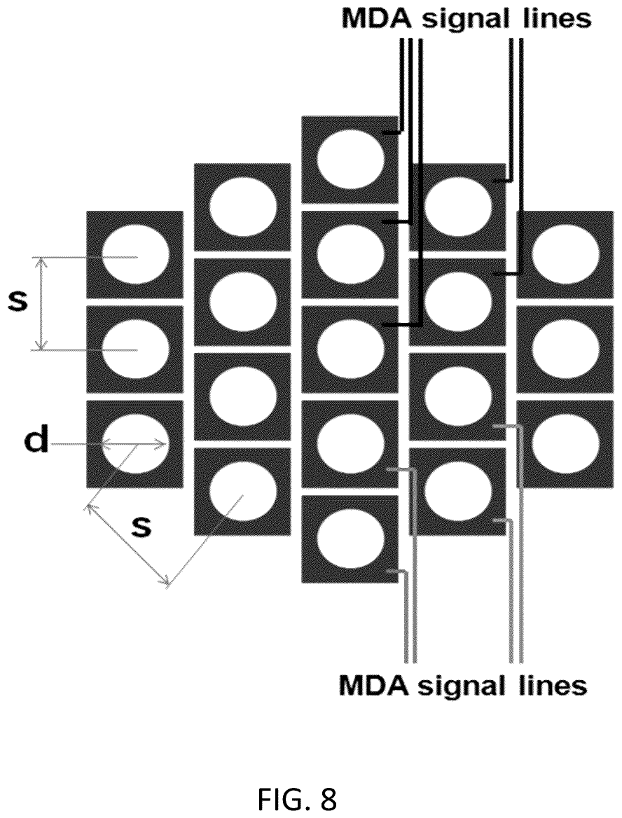

A hexapole single-polarity electrostatic deflector, as shown in FIG. 6, can be used as a micro deflector. The electrode plate with a zero (0 V) voltage may be grounded. Only one signal line may be used to deliver the deflection voltage (V) for the y-deflection of an electron beamlet. For example, the embodiment of FIG. 8 may be used to achieve this function. To achieve most homogeneous deflection fields, the plate angle β and gap angle δ meet the conditions as follows.

$$β + δ = 2 {0}^{0}$$

Further information about this determination can be found in U.S. Pat. No. 10,748,739, which is incorporated by reference in its entirety.

With computer simulations, FIG. 7 shows the homogenous deflection field of a hexapole single-polarity deflector. The beamlet size (e.g., 2r) is normally less or equal to the half of the deflector inner size (e.g., 2R) in FIG. 6, inside which the deflection field is sufficiently uniform (referring to FIG. 7) for introducing negligible deflection blurs. With the least signal line (i.e., only one), a portion of space is saved for designing the shields to reduce or avoid crosstalk between micro deflectors.

The hexapole single-polarity deflector in FIG. 6 or FIG. 7 can be used for one-direction deflection. For example, applying a positive signal V (or negative signal-V) on the plates in FIG. 6, the electron beamlet is deflected in +y-axis or −y-axis. If the deflector is rotated an angle of 90 degrees, the electron beam is deflected in +x-axis or −x-axis direction. Accordingly, if FIG. 4 is considered as the hexagon distribution of 331 electron spots on the IIP, each corresponding micro deflector in the magnetic image lens principal plane may be properly rotated and fixed in micro deflector array micro-fabrications. Because the micro deflector array is deployed in the magnetic image lens principal plane, the hexagon pattern of all beam spots can remain the same even if they are collectively rotated with the variations of magnetic image lens excitations for canceling field curvatures.

A single-polarity hexapole deflector can provide the same optical performance as a dual-polarity octupole deflector or a dual-polarity dodecapole deflector. However, the single-polarity hexapole deflector can be used in integration of a micro deflector array because of fewer signal lines. The density of integration of a micro deflector array with a single-polarity hexapole may be raised due to a reduction of the signal lines compared to using a conventional octupole deflector.

FIG. 8 shows the schematic of a micro deflector array integration. Each micro deflector is rotated, although the rotation is not shown in FIG. 8. The magnetic image lens in FIG. 5 can be a magnetic lens, so all the beamlets can be collectively rotated. All micro deflectors may be integrated on an insulation substrate (e.g., a silicon insulation thin film like SiO₂), which is positioned around micro deflectors. The signal lines (e.g., 331 lines for deflecting 331 beams) may be integrated in the gaps between micro deflectors. These signal lines may be on the insulation substrate. The signal lines may be the conductive lines micro-fabricated on insulation layers, such as the conductive lines used in integrated circuit chips for connecting transistors. The inner diameter (d) of each micro deflector may be at least approximately 2× larger than the size of the apertures in aperture array (APA) to provided intended results, including astigmatism blur. The pitch between the micro deflectors can be approximately tens to hundreds of microns.

Coma blur, field curvature blurs, and astigmatism blurs in the intermediate image plane may occur due to the beamlet deflections in FIG. 2 or in FIG. 5. Coma blurs tend to be relatively small because they are directly proportional to square of the beamlet angle α and the angle α is generally small. Accordingly, the coma blurs may be negligible. The field curvature blurs are primarily corrected with the Lu-adjustable method described previously. Therefore, the deflection astigmatism blurs can be corrected separately.

Like the micro deflector array concepts described herein, a micro stigmator array can be used to correct the astigmatism blurs, as shown in FIG. 5. In the example of the beamlet arrangements of FIG. 4, a micro stigmator array includes 331 micro stigmators. Each micro stigmator can be separately controlled through an independent signal line and correct the corresponding beamlet astigmatism blur, which can include the astigmatism generated in the projection optics in FIG. 3.

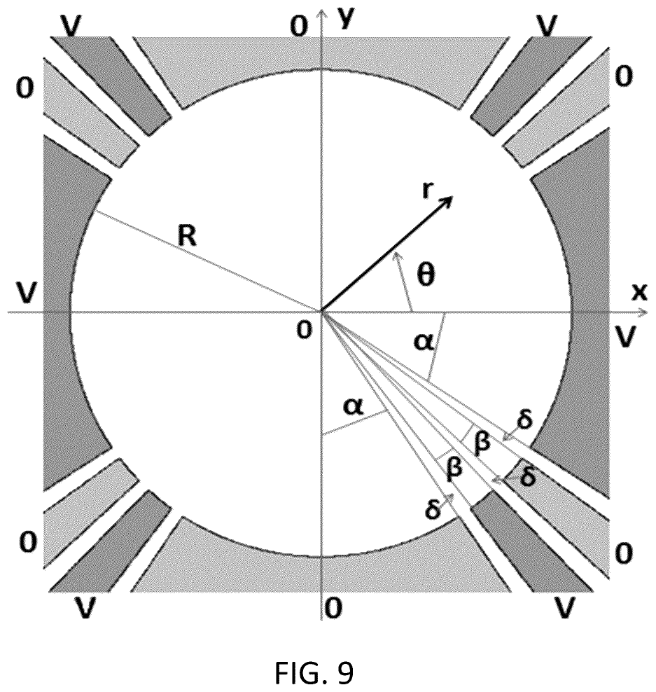

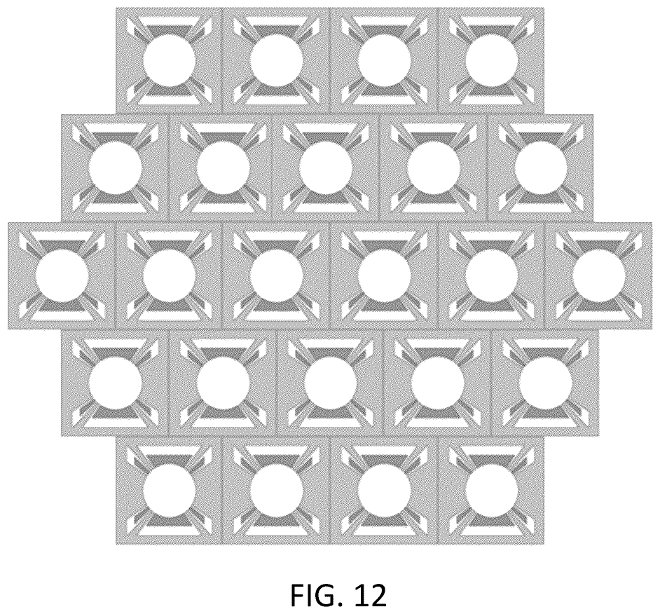

FIG. 9 shows an embodiment of a micro dodecapole stigmator. Only one signal line delivers the signal voltage of V to the plates. The signal line, which may be similar to that described in FIG. 8, may be a conductive line integrated between micro-stigmators in FIG. 12. The plates with a zero voltage may be grounded. The plate angles can be configured to minimize or eliminate the 4^{th} order octupole field and 6^{th} order dodecapole field. Higher order stigmator fields may change the shape of beam spots in the intermediate image plane or finally in the wafer. For examples, a 4^{th} order octupole field and a 6^{th} order dodecapole field may generate 4-petal and 6-petal beam spots, respectively.

To remove the 4^{th} and 6^{th} order stigmator fields, the plate angles α and β and the gap angle δ in FIG. 9 can be defined as follows.

$$β = 4 {5}^{0} - α - \frac{3}{2} δ$$

$$δ < 3 {0}^{0} - \frac{2}{3} α$$

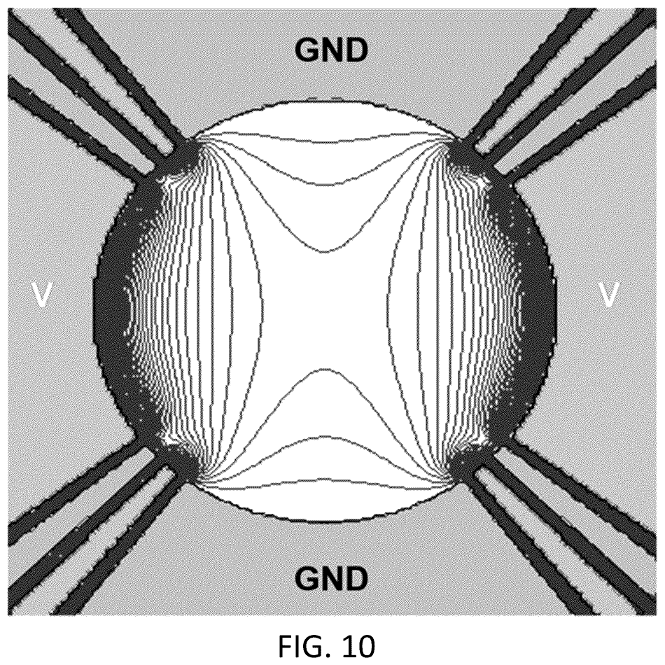

Using the conditions in the previous two equations, FIG. 10 shows the equipotential lines of a dodecapole micro stigmator, by which the 4^{th} order octupole field and 6^{th} order dodecapole fields are eliminated. The previous two equations are described in U.S. Pat. No. 11,056,312, which is incorporated by the reference in its entirety.

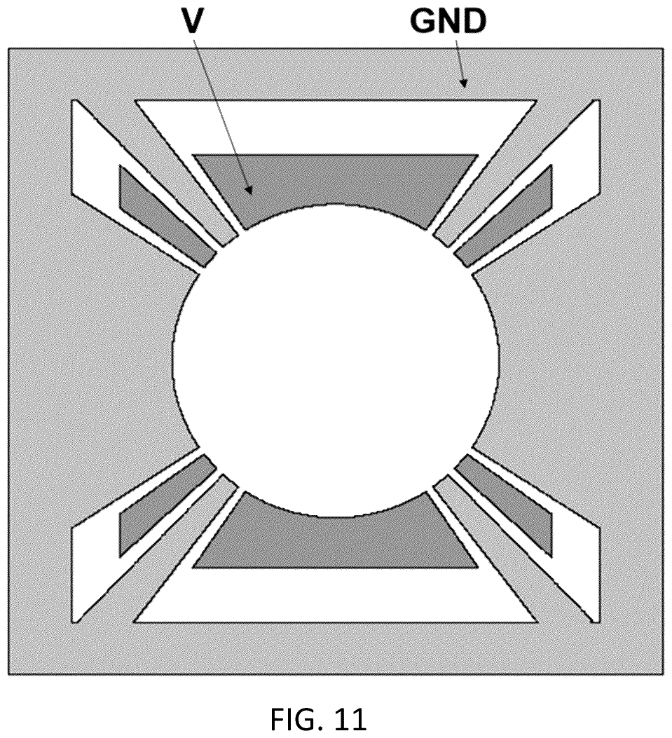

FIG. 11 shows an embodiment of a micro stigmator design on an insulation substrate for integration into a micro stigmator array chip. Only one addressable signal V may be required on the plates as shown. The other plates are connected together to share a common ground (GND). The plate angles and gap angle may be selected according to the previous two equations.

FIG. 12 shows the schematic of a micro stigmator array integration on an insulation substrate. The inner diameter of each micro stigmator may be around 2× larger than the size of the apertures in aperture array to provide the benefits described herein. The pitch between the micro stigmators is around tens-to-hundreds of microns. Each micro stigmator in FIG. 11 is arranged together with the same direction. The ground electrodes from each micro stigmator can be connected together to form a common ground (GND). Only one addressable signal line may be required for driving one individual micro stigmator, so the signal lines may be arranged with the same method as those in the integration of a micro deflector array (i.e., in FIG. 8).

The astigmatism blur can be characterized by an elliptic spot. For each beamlet, the direction of the elliptic spot (e.g., the long axis or short axis of an elliptic shape) can be randomly varied. To correct the astigmatism with a random direction for each beamlet, two micro stigmator arrays (i.e., two micro stigmator arrays) arranged in the optical axis with a rotation-angle difference of 45 degrees may be used. The construction of the two micro stigmator arrays is referred to as a micro stigmator array stack.

The two micro stigmator arrays may be separated by an insulation membrane with a thickness of microns. Each micro stigmator in one of the micro stigmator arrays can be addressed separately by the computer-addressable signal lines as, for example, shown in FIG. 8.

The 4^{th} order octupole field and 6^{th} order dodecapole field can be automatically eliminated by configuring the plate angles, such that the beamlet spot shape is kept round (i.e., no 4-petal or 6-petal beam spots). Only one signal line may be used for one individual micro stigmator, which can increase the density of micro stigmator array integration for using more electron beamlets with higher throughput. With the micro stigmator array stack, a random astigmatism elliptic spot may be corrected.

Using the embodiments disclosed herein, an electron beam can be generated using an electron beam source (e.g., a thermal field emission source). The electron beam is directed through a gun lens. Then the electron beam is directed through an aperture array thereby dividing the electron beam into a plurality of beamlets. Each of the beamlets is telecentric. The aperture array is downstream of the gun lens relative to a path of the electron beam. The beamlets can be directed through a global imaging lens. The beamlets can be focused onto an intermediate image plane using the global imaging lens.

The beamlets can be deflected using a micro deflector array disposed on a plane of the global imaging lens. The micro deflector array can include deflectors that are configured to be individually controlled. Each of the beamlets has one of the deflectors.

The beamlets can be directed through a global transfer lens and a global objective lens. The global transfer lens is disposed in a path of the beamlets between the global objective lens and the global imaging lens. The path of the beamlets forms a crossover between the global transfer lens and the global objective lens.

The beamlets can be directed through a micro stigmator array and a ground electrode plate. The ground electrode plate is disposed along the path of the beamlets between the aperture array and the micro deflector array. The micro stigmator array is disposed along the path of the beamlets between the aperture array and the ground electrode plate.

The beamlets can be used to image a workpiece, such as a semiconductor wafer, in a path of the beamlets. A detector can receive the beamlets reflected from the workpiece. Information from the detector can be used to generate an image of a region of the workpiece.

While described with respect to an electron beam, the embodiments disclosed herein also can be used with an ion beam or another charged particle beam. With an ion beam, the charged particle beam source may be an ion source such as an indirectly heated cathode.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron beam source configured to generate an electron beam;
a gun lens disposed in a path of the electron beam;
an aperture array that divides the electron beam into a plurality of beamlets, wherein each of the beamlets is telecentric;
a global imaging lens that receives the beamlets from the aperture array; and
a micro deflector array disposed on a plane of the global imaging lens, wherein the micro deflector array includes a plurality of deflectors configured to be individually controlled.

2. The system of claim 1, wherein the electron beam source is a thermal field emission source.

3. The system of claim 1, wherein the global imaging lens focuses the beamlets onto an intermediate image plane.

4. The system of claim 1, further comprising a global transfer lens and a global objective lens, wherein the global transfer lens and the global objective lens are in a path of the beamlets, wherein the global transfer lens is disposed in the path of the beamlets between the global objective lens and the global imaging lens, and wherein the path of the beamlets forms a crossover between the global transfer lens and the global objective lens.

5. The system of claim 1, wherein the global imaging lens is a magnetic lens, and wherein the micro deflector array is disposed on a principal plane between pole pieces of the global imaging lens.

6. The system of claim 5, further comprising a micro stigmator array and a ground electrode plate disposed in the path of the beamlets, wherein the ground electrode plate is disposed along the path of the beamlets between the aperture array and the micro deflector array, and wherein the micro stigmator array is disposed along the path of the beamlets between the aperture array and the ground electrode plate.

7. The system of claim 1, wherein the deflectors are each a hexapole, single polarity electrostatic deflector.

8. The system of claim 7, wherein the deflectors are disposed on an insulation substrate.

9. The system of claim 7, wherein a diameter of an aperture of the deflectors is at least two times larger than an aperture of the aperture array.

10. The system of claim 1, wherein the beamlets are configured in a hexagon array.

11. A method comprising:
generating a charged particle beam using a charged particle beam source;
directing the charged particle beam through a gun lens;
directing the charged particle beam through an aperture array thereby dividing the particle beam into a plurality of beamlets, wherein each of the beamlets is telecentric, and wherein the aperture array is downstream of the gun lens relative to a path of the particle beam;
directing the beamlets through a global imaging lens; and
deflecting the beamlets using a micro deflector array disposed on a plane of the global imaging lens, wherein the micro deflector array includes a plurality of deflectors configured to be individually controlled.

12. The method of claim 11, wherein the charged particle beam is an electron beam and the charged particle beam source is a thermal field emission source.

13. The method of claim 11, further comprising focusing the beamlets onto an intermediate image plane using the global imaging lens.

14. The method of claim 11, further comprising directing the beamlets through a global transfer lens and a global objective lens, wherein the global transfer lens is disposed in a path of the beamlets between the global objective lens and the global imaging lens, and wherein the path of the beamlets forms a crossover between the global transfer lens and the global objective lens.

15. The method of claim 14, further comprising directing the beamlets through a micro stigmator array and a ground electrode plate, wherein the ground electrode plate is disposed along the path of the beamlets between the aperture array and the micro deflector array, and wherein the micro stigmator array is disposed along the path of the beamlets between the aperture array and the ground electrode plate.

16. The method of claim 11, wherein the deflectors are each a hexapole, single polarity electrostatic deflector.

17. The method of claim 16, wherein the deflectors are disposed on an insulation substrate.

18. The method of claim 16, wherein a diameter of an aperture of the deflectors is at least two times larger than an aperture of the aperture array.

19. The method of claim 11, wherein the beamlets are configured in a hexagon array.

20. The method of claim 11, wherein field curvature blurs from all the beamlets are self-controllably corrected by adjusting image lens excitations of the global imaging lens.
